(19) United States
(12) Patent Application Publication
(10) Pub. No.: US 2026/0300597 A1
(43) Pub. Date: Oct. 1, 2026

(54) METHOD FOR DESIGNING INTEGRATED CIRCUIT

(71) Applicant: TAIWAN SEMICONDUCTOR MANUFACTURING COMPANY LTD., HSINCHU (TW)

(72) Inventors: WEI-MING CHEN, KEELUNG CITY (TW); HSIEN YU TSENG, MIAOLI COUNTY (TW)

(21) Appl. No.: 19/093,305

(22) Filed: Mar. 28, 2025

(51) Int. Cl. G06F 30/392; G06F 30/323; G06F 30/394

(52) U.S. Cl. CPC G06F 30/392; G06F 30/323; G06F 30/394

(57) ABSTRACT

A method for designing an integrated circuit (IC) is provided. A first layout of a design is obtained. The first layout corresponds to a first process. A plurality of parasitic parameters are extracted from the first layout. The parasitic parameters are scaled according to a first model corresponding to the first process and a second model corresponding to a second process. A pre-layout simulation is performed based on a schematic netlist of the design with the scaled parasitic parameters. A second layout corresponding to the second process is generated according to the schematic netlist and the scaled parasitic parameters after the pre-layout simulation is normal.

### BACKGROUND

In the realm of integrated circuits (IC), as semiconductor process technology progresses from an older node to a newer one, it is standard practice to shrink, scale, or migrate a circuit design from its initial implementation under the older semiconductor process technology node to a corresponding implementation under the newer node. This migration typically offers several advantages, such as reduced device sizes, enhanced operational speeds, lower costs, extended life cycles, and other similar benefits.

The migration process of an existing IC design from one technology to another typically involves automated synthesis software tools that can take a netlist description of the IC and map it into an equivalent netlist of the latest target technology. However, this process is time-consuming.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or decreased for clarity of discussion.

FIG. 1 is a flowchart of an IC design method, in accordance with some embodiments of the present disclosure.

FIG. 2 is a flowchart of an exemplary IC design migration method, in accordance with some embodiments of the present disclosure.

FIG. 3 is a flowchart of an exemplary resistance and capacitance (RC) estimation method, in accordance with some embodiments of the present disclosure.

FIG. 4 shows a schematic diagram illustrating the derived parameters in FIG. 3.

FIG. 5 shows a schematic diagram illustrating a parasitic resistance calculation for the target wire in a metal layer, in accordance with some embodiments of the present disclosure.

FIG. 6 shows a schematic diagram illustrating a parasitic capacitance calculation for the target wire in a metal layer, in accordance with some embodiments of the present disclosure.

FIG. 7 shows various sets of RC combinations, in accordance with some embodiments of the present disclosure.

FIGS. 8A and 8B show an exemplary by-layer RC scaling operation, in accordance with some embodiments of the present disclosure.

FIGS. 9A and 9B show an exemplary by-size RC scaling operation, in accordance with some embodiments of the present disclosure.

FIG. 10 shows an exemplary net merging operation, in accordance with some embodiments of the present disclosure.

FIG. 11 show an exemplary net splitting operation, in accordance with some embodiments of the present disclosure.

FIG. 12 is a schematic diagram showing an IC manufacturing system in accordance with some embodiments of the present disclosure.

FIG. 13 is a schematic diagram of a system implemented in the design house of FIG. 12, in accordance with some embodiments of the present disclosure.

### DETAILED DESCRIPTION

The following disclosure provides many different embodiments, or examples, for implementing different features of the provided subject matter. Specific examples of components and arrangements are described to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath”, “below”, “above”, “upper”, “lower”, “left”, “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

According to the embodiments, a design migration method is provided. An original layout of a design in a first process is obtained, and the parasitic parameters are extracted from the original layout and scaled based on the models of the first and second processes. A pre-layout simulation is performed based on the schematic netlist of the design and the scaled parasitic parameters. The routing constraints are obtained according to the scaled parasitic parameters after the pre-layout simulation is successful. A new layout is obtained by performing placement and routing based on the schematic netlist of the design and the routing constraints. By using the existing layout to verify circuit performance in pre-layout simulation with process evolution consideration, the iteration time for design migration is decreased, thereby enhancing design efficiency.

Integrated circuits (ICs) include a number of devices such as transistors, resistors and capacitors. These devices are initially isolated and are later interconnected using metal lines formed in multiple metallization layers overlying the circuit devices. The metal lines connect individual devices to form a circuit or a cell, including supplying power to the circuit (or cell), and connecting circuits (or cells) to each other globally (i.e., on a chip-level) to implement the intended function of the ICs. Cell placement and routing of metal lines are part of an overall design process for the ICs.

In IC manufacturing, a device scaling-down process, or “shrink,” occurs as advanced technology nodes (e.g., 10, 7, 5, 3 nm technology nodes) are developed. An IC or its layout is scaled down from a larger size to a smaller size during the shrink process. ICs and layouts are scaled to fit more devices onto a substrate, increasing performance in successive generations of semiconductor devices. ICs and layouts are scaled to decrease power consumption and accommodate smaller dimensions.

When scaling the devices in the IC, the interconnection metal lines used to connect the devices also shrink in at least one dimension. Thus, in some embodiments, a device shrink is accompanied by a decrease in line width for interconnection metal lines. However, a decrease in line width increases the resistance of a net (i.e., a conductive path between nodes or terminals of semiconductor devices that collectively form electrical circuits) formed from metal lines, which degrades IC performance (e.g., RC delay). Therefore, during process migration, the IC design and/or layout will be modified to achieve better performance.

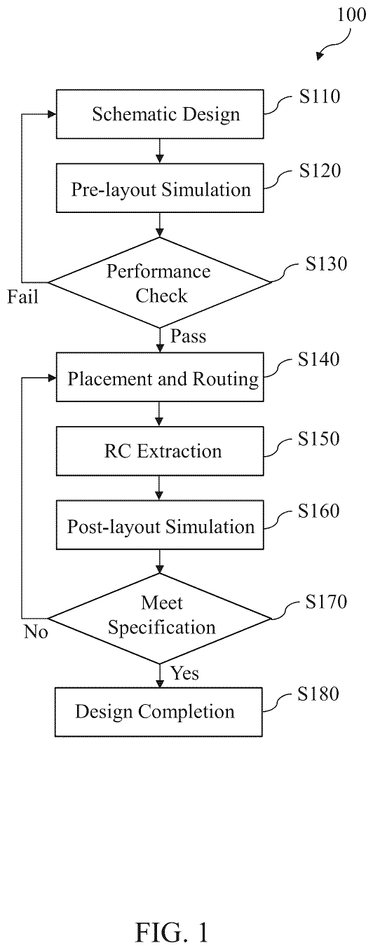

FIG. 1 is a flowchart of an IC design method 100, in accordance with some embodiments of the present disclosure. The IC design method 100 utilizes at least one electronic design automation (EDA) tool and at least one fabrication tool to carry out one or more operations in IC design method 100. In some embodiments, the EDA tool is one or more sets of executable instructions for execution by a processor or controller or a programmed computer to perform the indicated functionality. In some embodiments, operations in the IC design method 100 may be performed by different entities such as a design house, a mask house, and/or a semiconductor device manufacturer/fabricator (“fab”), that interact with one another in design, development, and manufacturing cycles and/or services related to ICs. In some embodiments, two or more of design house, mask house and fab is owned by a single larger company, and thus the IC design method 100 may be performed by a single entity. In some embodiments, two or more of design house, mask house and fab coexist in a common facility and thus can use common resources to perform the IC design method 100. The IC design method 100 is exemplary. Modifications to operations in the IC design method 100, such as change of order for the operations, partition of the operations, and deletion or addition of operations, are within the contemplated scope of the present disclosure.

In operation S110, a design of an IC (or a circuit) is provided by a circuit designer. In some embodiments, the design includes a schematic, i.e., an electrical diagram, of the IC or circuit. In some embodiments, the schematic is generated or provided in the form of a schematic netlist, such as a Simulation Program with Integrated Circuit Emphasis (SPICE) netlist. Other data formats for describing the design are usable in some embodiments.

In operation S120, a pre-layout simulation is performed, e.g., by a simulator, on the design to obtain the simulation results. In some embodiments, the simulator may simulate or predict the performance of the design in response to various conditions applied. In some embodiments, a SPICE simulation is performed on the SPICE netlist. In some embodiments, other simulation tools can be used in place of or in addition to the SPICE simulation.

In operation S130, a performance of the simulation results is checked to determine whether the design meets a predetermined specification, i.e., it is determined whether the pre-layout simulation is abnormal (unsuccessful or failed) or normal (successful). If the design does not meet the predetermined specification, e.g., some of the functions fail the verification in the simulation, the flow returns to operation S110, and the schematic design is redesigned (or modified). After the simulation results pass the check, the IC design passes a preliminary verification, and the front-end design process is completed. Next, a back-end physical design process follows.

In operation S140, placement and routing are performed to generate a layout (or layout diagram) of the IC based on the design. In some embodiments, the layout is generated in the form of a Graphic Design System (GDS) file by an EDA tool. In some embodiments, other tools and/or data formats for describing the layout are usable. During operation S140, a physical architecture representing the IC or circuit, as determined during the front-end process, is implemented. The layout development involves a placement operation and a routing operation in sequence. The detailed structure and associated geometry of the devices (e.g., transistors) of IC are determined during the placement operation. Interconnects between different devices are routed after the placement operation. Both placement and routing operations are performed to meet a layout-versus-schematic (LVS) check and a design rule check (DRC), ensuring the IC meets manufacturing requirements. Once the placement and routing of operation S140 are completed, a placed-and-routed layout is created, and a netlist along with data on placement and routing is generated accordingly.

The LVS check is performed to ensure that the generated layout corresponds to the design. Specifically, an LVS checking tool, i.e., an EDA tool, recognizes electrical components as well as connections therebetween from the pattern of the generated layout. The LVS checking tool then generates a layout netlist representing the recognized electrical components and connections. The layout netlist generated from the layout is compared, by the LVS checking tool, with the schematic netlist of the design. If the two netlists match within a matching tolerance, the LVS check is passed. Otherwise, correction is made to at least one of the layout or the design.

The DRC is performed, e.g., by an EDA tool, on the GDS file representing the layout, to ensure that the layout satisfies certain manufacturing design rules, i.e., to ensure the manufacturability of the IC. If one or more design rules are violated, corrections are made to at least one of the layout or the design. Examples of design rules include, but are not limited to, a width rule which specifies a minimum width of a pattern in the layout, a spacing rule which specifies a minimum spacing between adjacent patterns in the layout, an area rule which specifies a minimum area of a pattern in the layout, or the like.

In some embodiments, at least one of the design rules is voltage-dependent. For example, a metal-to-via spacing rule specifies a minimum spacing between a metal pattern and an adjacent via in the layout of the IC. In some embodiments, such a minimum spacing is dependent on a voltage expected or predicted to occur at the metal pattern or the via during an operation of the IC. Examples of further voltage-dependent design rules include, but are not limited to, metal-to-metal spacing rule, polysilicon-to-oxide definition (PO-to-OD) spacing rule, PO-to-PO spacing rule, and so on. A DRC that is performed to check compliance of a layout with one or more voltage-dependent design rules is referred to as a VDRC.

In operation S150, a resistance and capacitance (RC) extraction is performed to determine the layout-dependent parameters, e.g., parasitic resistances and parasitic capacitances, of interconnects in the IC layout for simulations (e.g., timing and loading) in a subsequent operation. Subsequently, a post-layout netlist, which includes the layout-dependent parameters, is generated. In some embodiments, the post-layout netlist data is a standard parasitic format (SPF) data.

In operation S160, a post-layout simulation is performed by a simulation tool, i.e., a simulator, according to the post-layout netlist with the extracted parasitic parameters obtained in operation S150. In some embodiments, the post-layout simulation is performed to minimize possibilities of electrical issues or layout difficulties during the chip manufacturing process.

In operation S170, it is determined whether the post-layout simulation meets a predetermined specification. A simulation of transistor-level behavior is conducted to examine whether the chip performance meets the required system specifications. If the simulation indicates that the layout does not meet the predetermined specification, e.g., if the parasitic parameters cause undesirable delays, corrections are made to at least one of the layout or the design. For example, the layout is re-developed to fix issues from a physical perspective, or the design is modified in case the problems cannot be resolved within the back-end physical design process. If the simulation indicates that the layout meets the predetermined specification, the design is completed in operation S180, and the layout is passed to manufacture or additional verification processes.

One or more photomasks are fabricated based on the post-layout netlist. For example, a mask house uses the layout accepted in the operation S140 to manufacture one or more photomasks (or reticles) for fabricating the various layers of IC according to layout. ICs are fabricated on a wafer using the photomasks. The fabrication may involve various semiconductor manufacturing processes, such as photolithography, etching, deposition, and thermal diffusion. In some embodiments, a testing operation may be utilized to ensure physical and functional integrity of the fabricated ICs. A singulation operation is used to separate the wafer into individual IC devices (or dies), thus completing the fabrication of the IC devices.

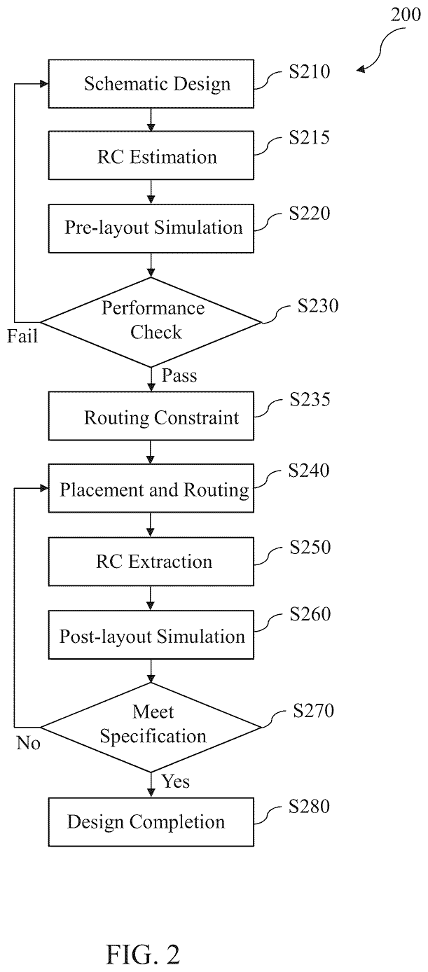

FIG. 2 is a flowchart of an exemplary IC design migration method 200, in accordance with some embodiments of the present disclosure. The IC design migration method 200 utilizes at least one EDA tool and at least one fabrication tool to carry out one or more operations in the IC design migration method 200. Modifications to operations in the IC design migration method 200, such as change of order for the operations, partition of the operations, and deletion or addition of operations, are within the contemplated scope of the present disclosure.

In operation S210, a design of an IC (or a circuit) for migration, hereinafter referred to as the migration design, is obtained for transitioning from previous-generation to next-generation technology (or from an old process to a new process). In some embodiments, the migration design includes a schematic design, i.e., an electrical diagram, and a layout of the IC or circuit implemented in the old process. In some embodiments, the schematic design is generated or provided in the form of a schematic netlist, such as a SPICE netlist. In some embodiments, other data formats for describing the migration design are usable. Furthermore, the layout of the schematic design, hereinafter referred to as the existing layout, is obtained from previous processes or older generations of processes. Moreover, a layout netlist is extracted from the existing layout. In some embodiments, the critical dimensions or gate structure configurations differ between the old and new processes or previous-generation and next-generation technologies.

In operation S215, a resistance and capacitance (RC) estimation is performed, to obtain estimated parameters, e.g., the scaled parasitic resistance and the scaled parasitic capacitance, for each wire (net or segment) in the extracted netlist from the existing layout. The extracted netlist includes the parasitic parameters obtained from the existing layout in operation S210. In some embodiments, the extracted netlist includes the SPF data. In some embodiments, the estimated parameters include one or more sets of scaled parasitic resistances and scaled parasitic capacitances for each wire.

In operation S220, a pre-layout simulation is performed, e.g., by a simulator, on the migration design with the estimated parameters to obtain the simulation results. In some embodiments, the simulator may simulate or predict the performance of the migration design under various conditions by using one or more sets of scaled parasitic resistances and scaled parasitic capacitances for each wire, e.g., stitching the scaled parasitic resistances and scaled parasitic capacitances to the schematic netlist of operation S210. In some embodiments, a SPICE simulation is performed on the SPICE netlist. In some embodiments, other simulation tools can be used in place of or in addition to the SPICE simulation. Through pre-layout simulation, the optimal estimated parameters are selected from one or more sets of scaled parasitic resistances and scaled parasitic capacitances for each wire based on performance, power, and area (PPA).

In operation S230, a performance of the simulation results is checked to determine whether the migration design meets a predetermined specification, i.e., it is determined whether the pre-layout simulation is abnormal or normal. If the migration design does not meet the predetermined specification, e.g., some of the functions fail the verification in the simulation, the flow returns to operation S210, and the schematic of migration design is redesigned (or modified). After the simulation results pass the check, the IC design passes a preliminary verification, and the front-end design process is completed. Next, a back-end physical design process follows.

In operation S235, the routing constraints are obtained according to the optimal estimated parameters for the wires in the migration design. In some embodiments, the routing constraints include wire routing constraints, such as the locations of wire terminal edges, width, spacing, alignment, resistance, and other attributes of the conductors.

In operation S240, placement and routing are performed to generate a layout (or layout diagram) of the IC based on the migration design and the routing constraints of operation S235. In some embodiments, the layout is generated in the form of a GDS file by an EDA tool. In some embodiments, other tools and/or data formats for describing the layout are usable. During operation S240, a physical architecture representing the IC or circuit, as determined during the front-end process, is implemented. The layout development involves sequential placement and routing operations. Compared with the operation S140 of FIG. 1, the routing operation is performed further according to the routing constraint of operation S235. Both placement and routing operations are performed to meet LVS and DRC checks, ensuring the IC meets manufacturing requirements. Once the placement and routing of operation S240 are completed, a placed-and-routed layout is created, and a netlist along with data on placement and routing is generated accordingly.

In operation S250, a RC extraction is performed to determine layout-dependent parameters, e.g., parasitic resistance and parasitic capacitance, of interconnects in the IC layout for simulations (e.g., timing and loading) in a subsequent operation. Subsequently, a post-layout netlist data, which includes the layout-dependent parameters, is generated. In some embodiments, the post-layout netlist data is a SPF data.

In operation S260, a post-layout simulation is performed by a simulation tool, i.e., a simulator, according to the post-layout netlist with the extracted parasitic parameters obtained in operation S250. In some embodiments, the post-layout simulation is performed to minimize possibilities of electrical issues or layout difficulties during the chip manufacturing process.

In operation S270, it is determined whether the post-layout simulation meets a predetermined specification. A simulation of transistor-level behavior is conducted to examine whether the chip performance meets the required system specifications. If the simulation indicates that the layout does not meet the predetermined specification, e.g., if the parasitic parameters cause undesirable delays, corrections are made to at least one of the layout or the design. For example, the layout is re-developed to fix issues from a physical perspective, or the design is modified in case the problems cannot be resolved within the back-end physical design process. If the simulation indicates that the layout meets the predetermined specification, the design is completed in operation S280, and the layout is passed to manufacture or additional verification processes.

In the IC design migration method 200 of FIG. 2, the pre-layout simulation of operation S220 takes into account parasitic resistance and parasitic capacitance in advance, based on the old parasitic parameters in existing layout. As a result, subsequent operations (e.g., placement and routing, and post-layout simulation) can be accelerated, allowing for more effectively and rapid optimization of design performance during process migration.

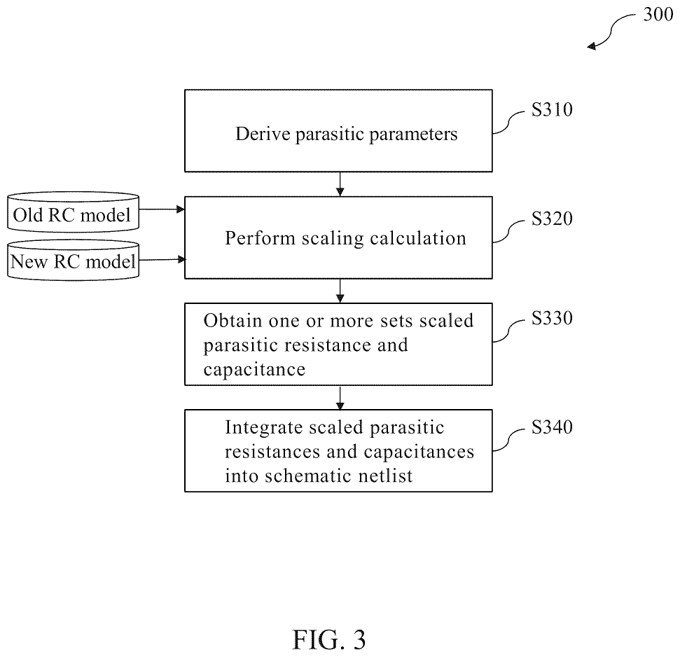

FIG. 3 is a flowchart of an exemplary RC estimation method 300, in accordance with some embodiments of the present disclosure. The RC estimation method 300 may be performed in operation S215 of FIG. 2.

In operation S310, the parasitic parameters are derived from the existing layout for each wire (or net or segment) in the extracted netlist. As described above, the extracted netlist is obtained from the existing layout corresponding to the migration design. Furthermore. The parasitic parameters include the parasitic capacitances and resistances.

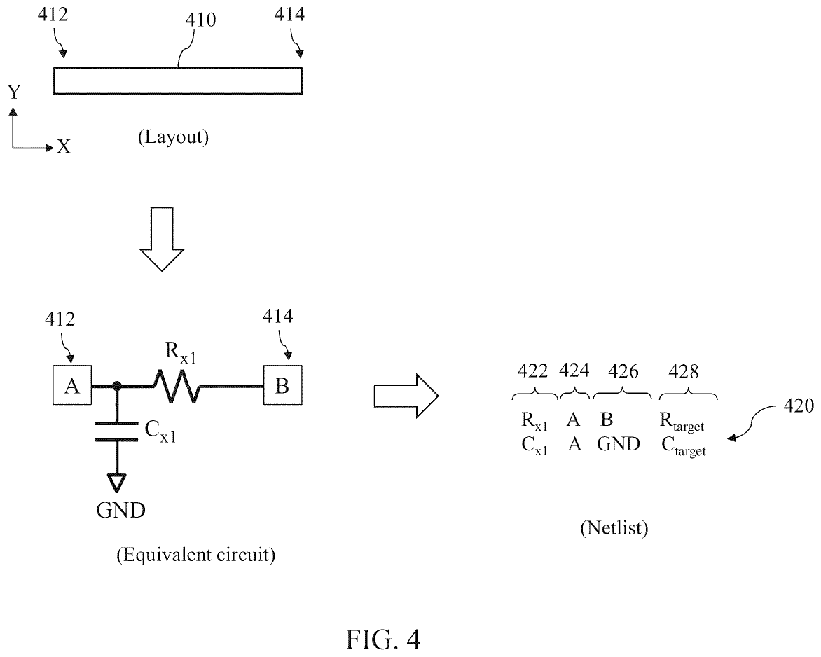

Referring to FIG. 4, FIG. 4 shows a schematic diagram illustrating the derived parameters in operation S310 of FIG. 3. In FIG. 4, the parasitic parameters are derived from the target wire 410 in the existing layout. The wire 410 is a target wire extending along the X-direction and has a first end 412 and a second end 414. The wire 410 has an equivalent circuit consisting of a parasitic resistor Rₓ₁ and a parasitic capacitor Cₓ₁. The parasitic resistor Rₓ₁ is coupled between a node A corresponding to the first end 412 and a node B corresponding to the second end 414. The parasitic capacitor Cₓ₁ is coupled between the node A and a ground GND. Thus, the RC netlist 420 of target wire 410 is obtained, where fields 422, 424, 426, and 428 respectively represent the component name, first connection node, second connection node and equivalent component value. In the embodiment of FIG. 4, the capacitance of the parasitic capacitor Cₓ₁ is C_{target}, and the resistance of the parasitic resistor Rₓ₁ is R_{target}.

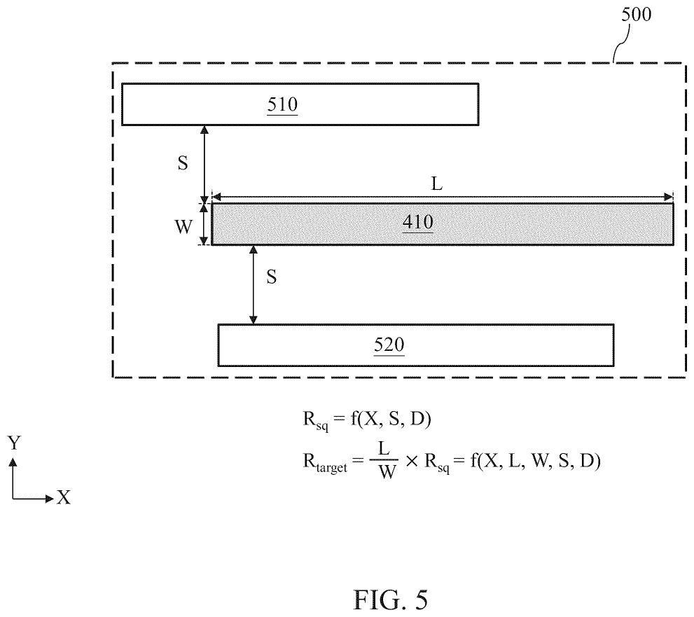

FIG. 5 shows a schematic diagram illustrating a parasitic resistance calculation for the target wire 410 in a metal layer X, in accordance with some embodiments of the present disclosure. In FIG. 5, a specific range 500 in a top view of the metal layer X from the existing layout is shown, and the specific range 500 includes the wires (or metal lines) 410, 510 and 520. The target wire 410 is separated from the wires 510 and 520 by the inter-metal dielectric (IMD) layer (not shown). The wire 410 is a target wire (or target segment) extending in the X-direction, and has a length L in the X-direction and a width W in the Y-direction. The wires 510 and 520 are neighboring wires adjacent to the target wire 410. The spacing between the target wire 410 and the wires 510 and 520 is S. Furthermore, the metal density of the wires 410, 510 and 520 within the specific range 500 is D. In the embodiment of FIG. 5, a square resistance R_{sq} (i.e., unit resistance) in the metal layer X is obtained as a function of the metal layer X, the spacing S and the metal density D. Furthermore, according to the square resistance R_{sq}, the length L and the width W (e.g., a function of the metal layer X, the length L, the width W, the spacing S and the metal density D), the parasitic resistance R_{target} of the target wire 410 is obtained.

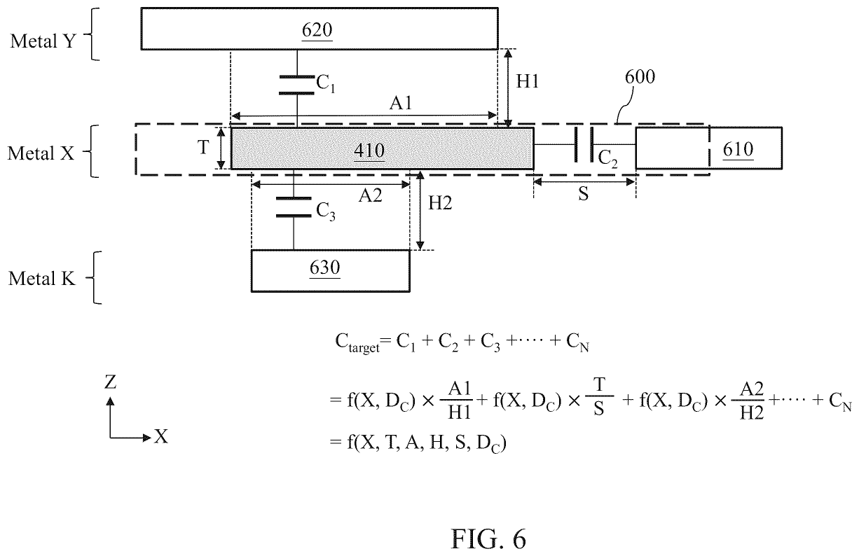

FIG. 6 shows a schematic diagram illustrating a parasitic capacitance calculation for the target wire 410 in a metal layer X, in accordance with some embodiments of the present disclosure. In FIG. 6, a specific range 600 in a cross-section view of the metal layer X from the existing layout is shown, and the specific range 600 includes the wires (or metal lines) 410 and 610. The wire 410 is a target wire (or target segment) extending in the X-direction, and has a thickness T in the Z-direction. The wire 610 is a neighboring wire adjacent to the target wire 410 in the same metal layer X, and has a thickness T in the Z-direction. The spacing between the target wire 410 and the neighbor wire 610 is S. The wire 620 is a neighboring wire adjacent to the target wire 410 in the metal layer Y, and the metal layer Y is disposed over the metal layer X. A height (or a distance) between the target wire 410 and the wire 620 is H1, and an overlapped area between the target wire 410 and the wire 620 is A1. The wire 630 is a neighboring wire adjacent to the target wire 410 in the metal layer K, and the metal layer K is disposed under the metal layer X. A height (or a distance) between the target wire 410 and the wire 630 is H2, and an overlapped area between the target wire 410 and the wire 620 is A2. In some embodiments, the heights H1 and H2 are the same. In some embodiments, the heights H1 and H2 are different. Furthermore, the metal density of the wires 410 and 610 within the specific range 600 is Dc. The target wire 410 is separated from the wires 610, 620 and 630 by the IMD layer (not shown).

In FIG. 6, a parasitic capacitor C₁ is present between the wires 410 and 620; a parasitic capacitor C₂ is present between the wires 410 and 610; and a parasitic capacitor C₃ is present between the wires 410 and 630. The capacitance of a parasitic capacitor between two wires is determined by the overlap area and the separation distance between the two wires. For example, the capacitance of the parasitic capacitor C₁ is equal to f(X,

$$Dc ) \times \frac{A 1}{H 1}$$

where permittivity ε is obtained from a function of the metal layer X and the metal density Dc, i.e., ε=f(X, Dc). In the embodiment of FIG. 6, the parasitic capacitance C_{target} of the target wire 410 is the sum of all parasitic capacitances of the target wire 410 and adjacent wires, i.e., C_{target}=C₁+C₂+C₃+. . . +C_{N}, and can be expressed as a function of the metal layer X, the thickness T, the overlapped area A, the height H, the spacing S, and the metal density Dc.

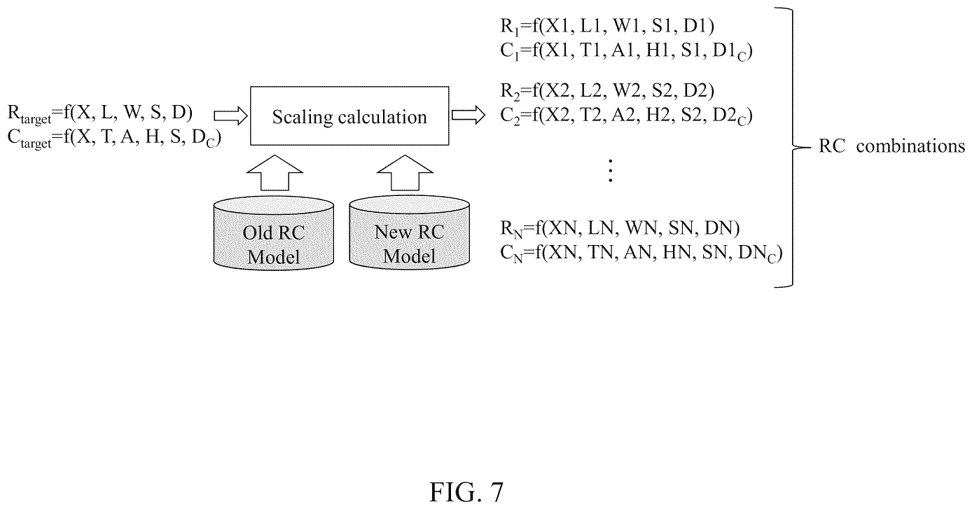

Referring back to the RC estimation method 300 in FIG. 3, a scaling calculation in operation S320 is performed based on the parasitic parameters (e.g., C_{target} and R_{target}) of operation S310, the old RC model corresponding to previous-generation technology (or old process), and the new RC model corresponding to next-generation technology(or new process), to obtain one or more sets of scaled parasitic resistances and scaled parasitic capacitances in operation S330, as shown in the N sets of RC combinations in FIG. 7. In some embodiments, the scaling calculation is performed through the following operations: by-layer RC scaling, by-size RC scaling, net merging and/or net splitting.

In operation S340, the scaled parasitic resistances and scaled parasitic capacitances are integrated into (or stitched to) the schematic netlist of operation S210 by merging scaled parasitic resistance and scaled parasitic capacitance into the schematic netlist of the migration design to obtain the pre-layout netlist with the parasitic parameters for the pre-layout simulation of operation S220 of FIG. 2.

Referring to FIG. 7, FIG. 7 shows a schematic diagram illustrating the scaling calculation in operation S320 of FIG. 3. N sets of RC combinations are obtained according to the parasitic parameters (e.g., C_{target} and R_{target}), the old RC model, and the new RC model. For example, assuming that the parasitic capacitance C_{target} is 100 p farad (F) and the parasitic resistance R_{target} is 100 ohm (Ω), by performing the scaling calculation, the scaled parasitic resistance R₁ is 90 Ω, and is obtained according to a function f(X1, L1, W1, S1, D1), where X1, L1, W1, S1 and D1 are modified based on the original X, L, W, S and D and the data from the old and new RC models. Similarly, by performing the scaling calculation, the scaled parasitic capacitance C₁ is 90 pF, and is obtained according to a function f(X1, T1, A1, H1, S1, D1c), where X1, T1, A1, H1, S1 and D1c are modified based on the original X, T, A, H, S and D and the data from the old and new RC models.

By performing the pre-layout simulation, the optimal scaled parasitic capacitance and resistance are obtained from the N sets of RC combinations. In some embodiments, the optimal scaled parasitic capacitance and resistance are the parasitic resistance and capacitance with the best pre-layout simulation performance among the N sets of RC combinations. In some embodiments, if no optimal scaled parasitic capacitance and resistance are obtained, the schematic design is modified, such as adjusting the size of active components connected to the target wire 410. Furthermore, a routing constraint for the target wire 410 is obtained according to the optimal scaled parasitic capacitance and resistance for placement and routing in operation S240.

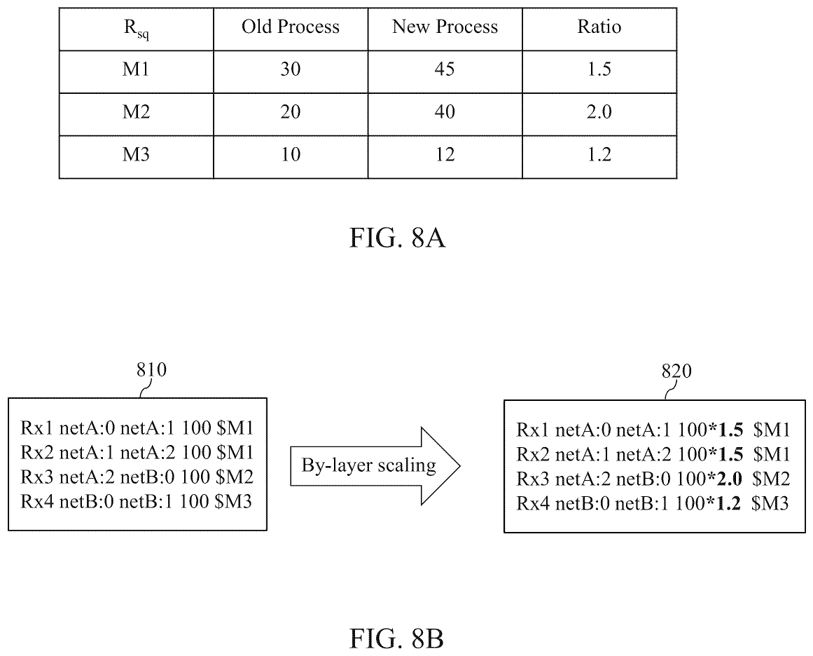

FIGS. 8A and 8B show an exemplary by-layer RC scaling operation, in accordance with some embodiments of the present disclosure.

In FIG. 8A, a table illustrating the square resistances of various metal layers in the old and new processes is shown. In the old process, the square resistances in the metal layers M1, M2 and M3 are 30 Ω, 20 Ω and 10 Ω, respectively. Furthermore, in the new process, the square resistances in the metal layers M1, M2 and M3 are 45 Ω, 40 Ω and 12 Ω, respectively. In this embodiment, the square resistances of the new process are greater than the square resistances of the old process. The scaling ratios of the square resistances in the metal layers M1, M2 and M3 between the new and old processes are 1.5, 2.0 and 1.2, respectively. Furthermore, the scaled parasitic resistance of the new process is obtained by multiplying the parasitic resistance of the target wire of the old process by the scaling ratio of the corresponding metal layer.

In FIG. 8B, the netlists 810 and 820 illustrating the by-layer RC scaling operation are shown according to the square resistances of FIG. 8A. The netlist 810 includes the parasitic resistors Rx1, Rx2, Rx3 and Rx4 extracted from the existing layout corresponding to the old process. The parasitic resistors Rx1 and Rx2 are disposed in the metal layer M1, the parasitic resistor Rx3 is disposed in the metal layer M2, and the parasitic resistor Rx4 is disposed in the metal layer M3. In the netlist 810, taking the parasitic resistor Rx1 as an example, the parasitic resistor Rx1 is formed in the metal layer M1 and is coupled between the nodes netA:0 and netA:1. Furthermore, the resistance of the parasitic resistor Rx1 is 100 Ω. Through the by-layer RC scaling operation, the scaled parasitic resistances of the parasitic resistors Rx1, Rx2, Rx3 and Rx4 are obtained. For example, in the netlist 820 corresponding to the new process, the resistances of the parasitic resistors Rx1 and Rx2 have increased to 1.5 times, the resistance of the parasitic resistor Rx3 has increased to 2 times, and the resistance of the parasitic resistor Rx4 has increased to 1.2 times.

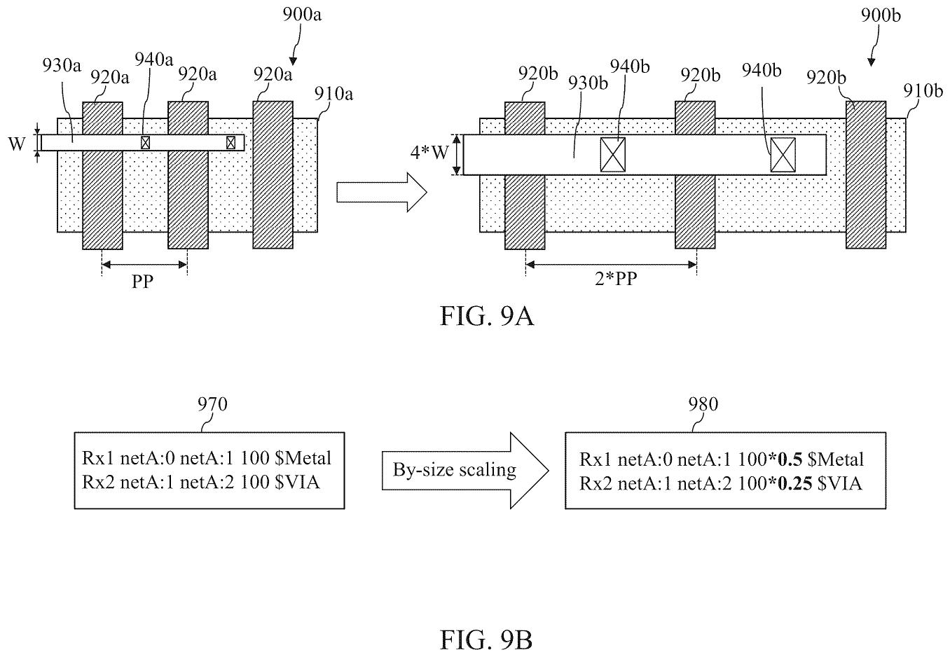

FIGS. 9A and 9B show an exemplary by-size RC scaling operation, in accordance with some embodiments of the present disclosure.

In FIG. 9A, the layouts 900a and 900b of the old and new processes, respectively, are shown. Some features, such as via, poly pitch, metal width, in the layouts 900a and 900b have different sizes. In the layout 900a of the old process, the active region 910a extends in the X-direction. Furthermore, the gate structures (or poly) 920a extend in the Y-direction and are disposed according to a poly pitch PP. The metal line 930a extends in the X-direction and has a width W, and the metal line 930a overlaps the two gate structures 920a on the left. Each via 940a is disposed on the metal line 930a and between two adjacent gate structures 920a. In the layout 900b of the new process, the active region 910b extends in the X-direction. Furthermore, the gate structures 920b extend in the Y-direction and are arranged according to a double poly pitch PP (e.g., 2*PP), so the length of the metal line 930b is twice the length of the metal line 930a. The metal line 930b extends in the X-direction and has four times width W (e.g., 4 W), and the metal line 930b overlaps the two gate structures 920b on the left. Therefore, assuming that the square resistances of the same metal layer of old and new processes are identical, the scaled parasitic resistance of the metal line 930b is equal to half the parasitic resistance of metal line 930a, e.g., R_{metal_new}=(2/4)*R_{metal_old}. The vias 940b are disposed on the metal line 930b and between the gate structures 920b. Moreover, the size of the via 940b is four times that of the via 940a. Therefore, assuming that the square resistances of the same via layer of old and new processes are identical, the scaled parasitic resistance of the via 940b is equal to one quarter of the parasitic resistance of via 940a, e.g., R_{via_new}=(1/4)*R_{via_old}.

In FIG. 9B, the netlists 970 and 980 illustrating the by-size RC scaling operation are shown according to the layouts of FIG. 9A. The netlist 970 includes the parasitic resistors Rx1 and Rx2 extracted from the existing layout corresponding to the old process. The parasitic resistor Rx1 is disposed in the metal layer, and the parasitic resistor Rx2 is disposed in the via layer. Through the by-size RC scaling operation, the scaled parasitic resistances of the parasitic resistors Rx1 and Rx2 are obtained. For example, in the netlist 980 corresponding to the new process, the resistance of the parasitic resistor Rx1 have decreased to 0.5 times, and the resistance of the parasitic resistor Rx2 has decreased to 0.25 times.

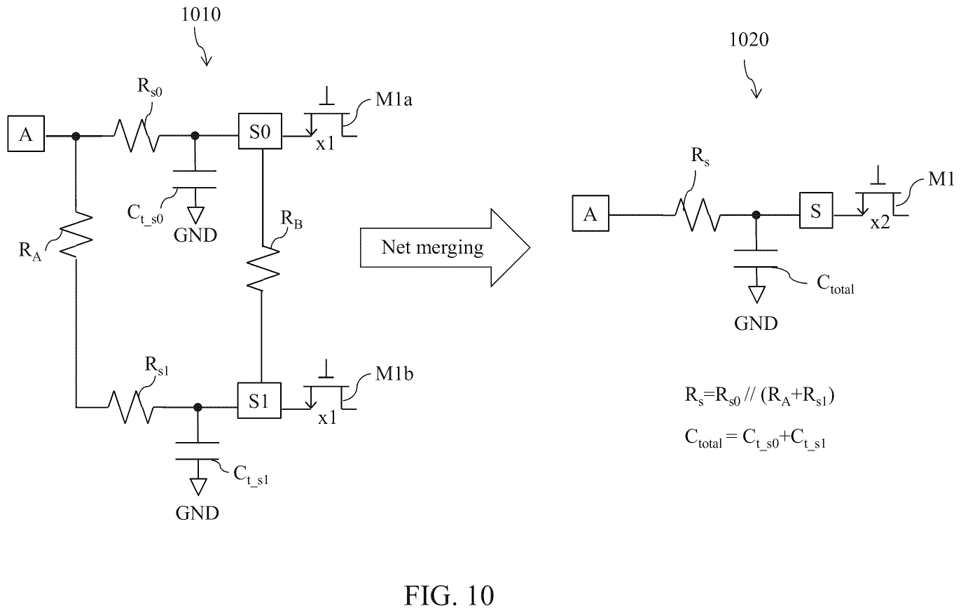

FIG. 10 shows an exemplary net merging operation, in accordance with some embodiments of the present disclosure. In FIG. 10, the extracted schematic 1010 includes the transistors M1a and M1b, the parasitic resistors Rₛ₀, Rₛ₁, R_{A} and R_{B}, and the parasitic capacitors C_{t_s0} and C_{t_s1} extracted from the exiting layout. The parasitic resistance and capacitance of each wire (or net) between two of the nodes A, S0 and S1 can be obtained according to the parasitic resistance R_{target} of FIG. 5 and the parasitic capacitance C_{target} of FIG. 6. The transistors M1a and M1b have the same size and same configuration in layout. The source of transistor M1a is coupled to the node S0, and the source of transistor M1b is coupled to the node S1. The parasitic resistor Rₛ₀ is coupled between the nodes A and S0. The parasitic resistors R_{A} and Rₛ₁ are coupled in series between the nodes A and S1. The parasitic resistor R_{B} is coupled between the nodes S0 and S1. The parasitic capacitor C_{t_s0} is coupled between the node S0 and the ground GND, and the parasitic capacitor C_{t_s1} is coupled between the node S1 and the ground GND. During the net merging operation, assuming that the node S0 is equal to node S1, that is, no current flows through the parasitic resistor R_{B}, the parasitic resistor R_{B} can be removed. If the resistance of the parasitic resistor Rₛ₀ is approximately equal to the sum of the resistances of the parasitic resistors R_{A} and Rₛ₁, the nodes S0 and S1 are merged as a single node S, and the transistors M1a and M1b are merged as a single transistor M1, as shown in the scaled schematic 1020.

Through the net merging operation, a first net between the nodes A and S0 and a second net between the nodes A and S1 in the extracted schematic 1010 are merged into a single net between the nodes A and S in the scaled schematic 1020. In the scaled schematic 1020, the source of transistor M1 is coupled to the node S, and the transistor M1 is twice the size of transistors M1a and M1b. The parasitic resistor Rₛ is coupled between the nodes A and S, and the resistance of the parasitic resistor Rₛ is obtained according to the parasitic resistors Rₛ₀, Rₛ₁, and R_{A}. Furthermore, the parasitic capacitor Cₜₒₜₐₗ is coupled between the node S and the GND, and the capacitance of the parasitic capacitor Cₜₒₜₐₗ is obtained according to the parasitic capacitors C_{t_s0} and C_{t_s1}.

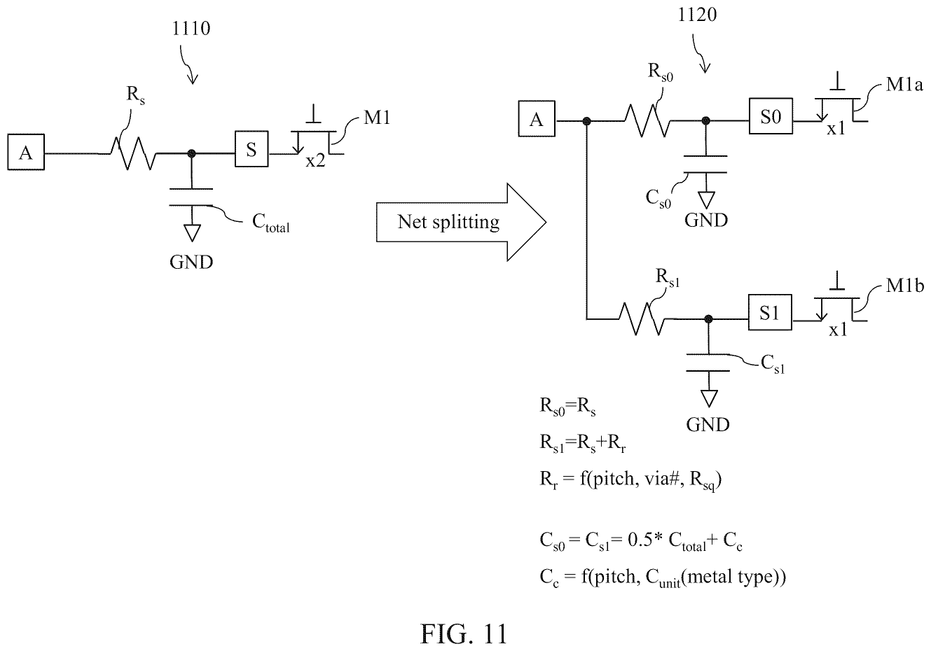

FIG. 11 show an exemplary net splitting operation, in accordance with some embodiments of the present disclosure. In FIG. 11, the extracted schematic 1110 includes the transistor M1, the parasitic resistor Rₛ and the parasitic capacitor Cₜₒₜₐₗ extracted from the exiting layout. The parasitic resistance and capacitance of the net between the nodes A and S can be obtained according to the parasitic resistance R_{target} of FIG. 5 and the parasitic capacitance C_{target} of FIG. 6. The source of transistor M1 is coupled to the node S. The parasitic resistor Rₛ is coupled between the nodes A and S, and the parasitic capacitor Cₜₒₜₐₗ is coupled between the node S and the ground GND. Through the net splitting operation, a single net between the nodes A and S in the extracted schematic 1110 is split into a first net between the nodes A and S0 and a second net between the nodes A and S1 in the extracted schematic 1110. In the scaled schematic 1120, the transistors M1a and M1b have the same size and same configuration in layout. The source of transistor M1a is coupled to the node S0, and the source of transistor M1b is coupled to the node S1. The parasitic resistor Rₛ₀ is coupled between the nodes A and S0, and the parasitic capacitor Cₛ₀ is coupled between the node S0 and the ground GND. The parasitic resistor Rₛ₁ is coupled between the nodes A and S1, and the parasitic capacitor Cₛ₁ is coupled between the node S1 and the ground GND. The parasitic resistors Rₛ₀ and Rₛ have the same resistance. The resistance of the parasitic resistor Rₛ₁ is determined according to the parasitic resistor Rₛ and the resistance Rᵣ, where the resistance Rᵣ is obtained according to the poly pitch of the transistors M1a and M1b (e.g., the poly pitch PP in FIG. 9A), the number of vias between the two poly of the transistors M1a and M1b (e.g., the number of the vias 940a between two gate structures 920a in FIG. 9A) and the square resistance R_{sq} of the corresponding metal layer. The parasitic capacitors Cₛ₀ and Cₛ₁ have the same capacitance, and is obtained according to the parasitic capacitor Cₜₒₜₐₗ and the capacitance C_{c}. The capacitance C_{c} is obtained according to the poly pitch of the transistors M1a and M1b (e.g., the poly pitch PP in FIG. 9A), and the unit capacitance Cᵤₙᵢₜ of the corresponding metal layer. In some embodiments, the unit capacitance Cᵤₙᵢₜ is obtained from the new RC model.

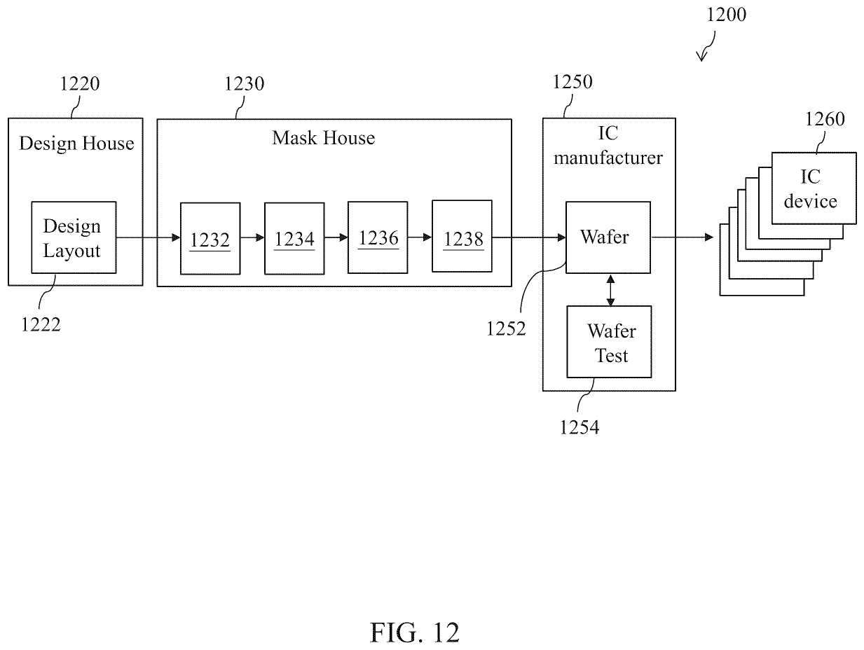

FIG. 12 is a schematic diagram showing an IC manufacturing system 1200 in accordance with some embodiments of the present disclosure. The IC manufacturing system 1200 is configured to manufacture an IC device (die or chip) 1260 through a plurality of entities, such as a design house 1220, a mask house 1230, and an IC manufacturer (fab or foundry) 1250. The entities within the IC manufacturing system 1200 are connected via a communication channel, e.g., a wired or wireless channel, and interact with one another through a network, such as an intranet or the internet. In some embodiments, the design house 1220, the mask house 1230 and the IC manufacturer 1250 belong to a single entity or are operated by independent parties.

The design house (or design team) 1220 generates a design layout 1222 in an IC design phase for the IC devices 160 to be fabricated. The design layout 1222 includes descriptions of various geometrical patterns intended to perform specific functions that conform to the performance and manufacturing specifications. The geometrical patterns represent circuit features in the fabricated IC devices 1260, e.g., metal layers, dielectric layers, or semiconductor layers, that form various IC components, such as an active region, a gate electrode, a source region or a drain region, and a conductive line or via of an interconnect structure (sometimes referred to as a redistribution layer). In an embodiment, the design house 1220 operates a circuit design procedure to generate the design layout 1222. The circuit design procedure may include, but is not limited to, logic design, physical design, pre-layout simulation, placement and routing, timing analysis, parameter extraction, design rule check and post-layout simulation. According to the methods (e.g., the IC design migration method 200 of FIG. 2 and the RC estimation method 300 of FIG. 3) as described and illustrated with reference to figures of the present disclosure, the design layout 1222 may be converted from description texts into their visual equivalents to show a physical layout of the depicted patterns, such as the dimensions, shapes and locations thereof. In some embodiments, the design layout 1222 can be expressed in a suitable file format such as GDSII, DFII, Oasis or the like.

The mask house 1230 receives the design layout 1222 from the design house 1220 and manufactures one or more masks according to the design layout 1222. In an embodiment, the mask house 1230 includes a mask data preparation block 1232, a mask fabrication block 1236 and a mask inspection block 1238. The mask data preparation block 1232 modifies the design layout 1222 so that a resulting design layout 1234 that enables a mask writer to convert the design layout 1222 into a writer-readable format. Generally, the design layout 1234 may include replicated cells thereon. When a mask with a mask pattern is formed, it is repeatedly used to transfer the patterns of the cells to a semiconductor wafer, wherein the pattern transfer is done with an exposure field in each shot. In addition, scribe line regions or test structures may be formed in spaces between the exposure fields. In some embodiments, the mask data preparation block 1232 is configured to determine the locations of dies that are to be included in a cell, the locations and widths of scribe line regions around the cells, and the locations and types of test structures to be formed in the scribe line regions.

The mask fabrication block 1236 is configured to form a mask with a mask pattern by preparing a substrate based on the design layout 1234 provided by the mask data preparation block 1232. A mask substrate is exposed to a radiation beam, such as an electron beam, based on the pattern of the design layout 1234 in a writing operation, which may be followed by an etching operation to leave behind the patterns corresponding to the design layout. In an embodiment, the mask fabrication block 1236 introduces a checking procedure to ensure that the layout data complies with requirements of a mask writer and/or a mask manufacturer and that the layout data can be used to generate the mask (photomask or reticle) as desired. An electron-beam (e-beam), multiple e-beams, an ion beam, a laser beam or other suitable writer source may be used to transfer the patterns. As a result, the patterns of the cells as acquired are transferred to a semiconductor substrate (such as a wafer) or material layers disposed on the semiconductor substrate. Moreover, the mask can be fabricated in various technologies. In an embodiment, the mask is fabricated using binary technology in which a binary mask includes a transparent substrate (e.g., fused quartz) and an opaque material (e.g., chromium) coated on the opaque regions of the mask. In another example, the mask is fabricated using a phase shift technology, e.g., a phase shift mask (PSM).

After the mask is fabricated, the mask inspection block 1238 inspects the fabricated mask to determine if any defects, such as full-height and non-full-height defects, exist in the fabricated mask. If any defects are detected, the mask may be cleaned or the design layout in the mask may be modified.

The IC manufacturer 1250 is an IC fabrication entity that includes multiple manufacturing facilities for the fabrication of a variety of different IC products. The IC manufacturer 1250 uses the mask fabricated by the mask house 1230 to fabricate a semiconductor wafer 1252 having a plurality of IC devices 1260 thereon. The semiconductor wafer 1252 may include a silicon substrate or another suitable substrate including various layers formed thereon. In an embodiment, the IC manufacturer 1250 includes a wafer testing block 1254 configured to ensure that the IC conforms to physical manufacturing specifications and mechanical and/or electrical performance specifications. In some embodiments, the test structures formed on the semiconductor wafer 1252 may be utilized to generate test data indicative of the quality of the semiconductor wafer 1252. After the semiconductor wafer 1252 passes the testing procedure performed by the wafer testing block 154, the semiconductor wafer 1252 may be diced (or sliced) along the scribe line regions to form separate IC devices 1260. The dicing process can be accomplished by scribing and breaking, by mechanical sawing (e.g., with a dicing saw) or by laser cutting.

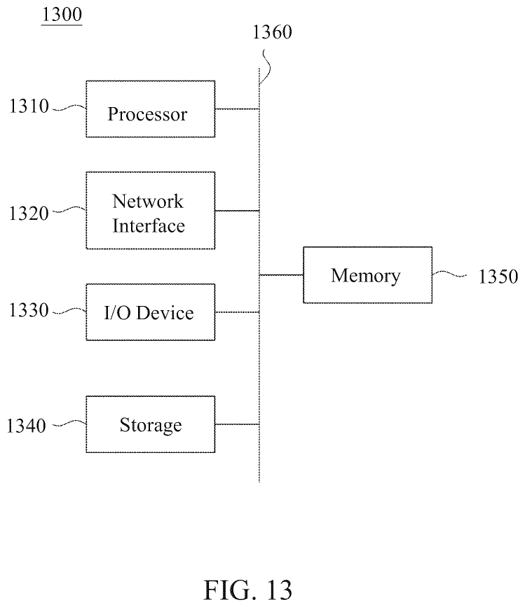

FIG. 13 is a schematic diagram of a system 1300 implemented in the design house 1220 of FIG. 12, in accordance with some embodiments of the present disclosure.

The system 1300 includes a processor 1310, a network interface 1320, an input and output (I/O) device 1330, a storage device 1340, a memory 1350, and a bus 1360. The bus 1360 couples the network interface 1320, the I/O device 1330, the storage device 1340, the memory 1350 and the processor 1310 to each other.

The processor 1310 is configured to execute program instructions that include a tool configured to perform the method as described and illustrated with reference to figures of the present disclosure. Accordingly, the tool is configured to execute operations, such as performing design, analysis and simulation operations and so on.

The network interface 1320 is configured to access program instructions and data accessed by the program instructions stored remotely through a network (not shown).

The I/O device 1330 includes an input device and an output device configured for enabling user interaction with the system 1300. In some embodiments, the input device includes, for example, a keyboard, a mouse, and other devices. Moreover, the output device includes, for example, a display, a printer, and other devices.

The storage device 1340 is configured to store program instructions and data accessed by the program instructions. In some embodiments, the storage device 1340 includes a non-transitory computer-readable storage medium, for example, a magnetic disk and an optical disk.

The memory 1350 is configured to store program instructions to be executed by the processor 1310 and data accessed by the program instructions. In some embodiments, the memory 1350 includes any combination of a random-access memory (RAM), some other volatile storage device, a read-only memory (ROM), and some other non-volatile storage device.

In some embodiments, the apparatus or manufacture comprising a computer usable or readable medium having control logic (software) stored thereon is also referred to herein as a computer program product or program storage device. This includes, but is not limited to, the system 1300 and the memory 1350, as well as tangible articles of manufacture embodying any combination of the foregoing. Such control logic, when executed by one or more data processing devices (such as the system 1300), causes such data processing devices to operate as described herein.

In some embodiments, the operations of embodiments, are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

The methods and operations described in this disclosure can be partially or fully embodied as code and/or data stored in a computer-readable storage medium or device, so that when a computer system reads and executes the code and/or data, the computer system performs the associated methods and processes. The methods and operations can also be partially or fully embodied in hardware modules or apparatuses, so that when the hardware modules or apparatuses are activated, they perform the associated methods and processes. Note that the methods and operations can be embodied using a combination of code, data, and hardware modules or apparatuses.

According to some embodiments, a method for designing an integrated circuit (IC) is provided. A first layout of a design is obtained. The first layout corresponds to a first process. A plurality of parasitic parameters are extracted from the first layout. The parasitic parameters are scaled according to a first model corresponding to the first process and a second model corresponding to a second process. A pre-layout simulation is performed based on a schematic netlist of the design with the scaled parasitic parameters. A second layout corresponding to the second process is generated according to the schematic netlist and the scaled parasitic parameters after the pre-layout simulation is normal.

According to some embodiments, a method for designing an integrated circuit (IC) is provided. A first layout of a design is obtained. The first layout corresponds to a first process. A plurality of parasitic parameters are extracted from a target object of the first layout. The parasitic parameters are scaled according to a first model corresponding to the first process and a second model corresponding to a second process. A pre-layout simulation is performed based on a schematic netlist of the design with the scaled parasitic parameters. The design corresponding to the target object is modified until the pre-layout simulation is normal. A second layout corresponding to the second process is generated according to the schematic netlist and the scaled parasitic parameters after the pre-layout simulation is normal.

According to some embodiments, a computer-readable storage medium storing instructions that, when executed by a processor, cause the processor to perform a method for designing an integrated circuit (IC) is provided. The method includes: obtaining a first layout of a design, wherein the first layout corresponds to a first process; extracting a plurality of parasitic parameters from the first layout; scaling the parasitic parameters according to a first model corresponding to the first process and a second model corresponding to a second process; performing a pre-layout simulation based on a schematic netlist of the design with the scaled parasitic parameters; and generating a second layout corresponding to the second process according to the schematic netlist and the scaled parasitic parameters after the pre-layout simulation is normal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for designing an integrated circuit (IC), comprising:
obtaining a first layout of a design, wherein the first layout corresponds to a first process;
extracting a plurality of parasitic parameters from the first layout;
scaling the parasitic parameters according to a first model corresponding to the first process and a second model corresponding to a second process;
performing a pre-layout simulation based on a schematic netlist of the design with the scaled parasitic parameters; and
generating a second layout corresponding to the second process according to the schematic netlist and the scaled parasitic parameters after the pre-layout simulation is normal.

2. The method of claim 1, further comprising:
manufacturing the IC with the second process based on the second layout, wherein critical dimensions in the first process and the second process are different.

3. The method of claim 1, wherein performing the pre-layout simulation based on the schematic netlist of the design with the scaled parasitic parameters further comprises:
integrating the scaled parasitic parameters into the schematic netlist to obtain integrated schematic netlist;
performing the pre-layout simulation on the integrated schematic netlist;
modifying the design when the pre-layout simulation is abnormal; and
generating a routing constraint according to the scaled parasitic parameters when the pre-layout simulation is normal.

4. The method of claim 3, wherein generating the second layout corresponding to the second process according to the schematic netlist and the scaled parasitic parameters further comprises:
performing a placement and routing operation according to the schematic netlist and the routing constraint to generate the second layout; and
performing a post-layout simulation based on the second layout.

5. The method of claim 1, wherein generating the second layout corresponding to the second process according to the schematic netlist and the scaled parasitic parameters further comprises:
obtaining a routing constraint according to the scaled parasitic parameters after the pre-layout simulation is normal;
performing a placement and routing operation according to the schematic netlist and the routing constraint to generate the second layout; and
performing a post-layout simulation based on the second layout.

6. The method of claim 1, wherein the parasitic parameters comprises at least one parasitic resistance and at least one parasitic capacitance of one wire in the first layout.

7. The method of claim 1, wherein scaling the parasitic parameters according to the first model corresponding to the first process and the second model corresponding to the second process further comprises:
obtaining a scaling ratio of square resistances in a first metal layer between the first and second processes; and
scaling parasitic resistances of the parasitic parameters in the first metal layer according to the scaling ratio.

8. The method of claim 1, wherein scaling the parasitic parameters according to the first model corresponding to the first process and the second model corresponding to the second process further comprises:
obtaining a scaling ratio of a specific feature according to sizes of the specific feature in the first and second processes; and
scaling parasitic resistances of the parasitic parameters for the specific feature according to the scaling ratio.

9. The method of claim 8, wherein the specific feature comprises a metal width, a via size or a poly pitch.

10. The method of claim 1, wherein scaling the parasitic parameters according to the first model corresponding to the first process and the second model corresponding to the second process further comprises:
obtaining a first parasitic parameter and a second parasitic parameter from the parasitic parameters, wherein the first and second parasitic parameters are extracted from two different wires connected to the same node in the first layout; and
merging the two different wires into a single wire in the second layout, wherein a third parasitic parameter of the single wire is obtained according to the first and second parasitic parameters.

11. The method of claim 1, wherein scaling the parasitic parameters according to the first model corresponding to the first process and the second model corresponding to the second process further comprises:
obtaining a first parasitic parameter from the parasitic parameters, wherein the first parasitic parameter is extracted from a single wire in the first layout; and
splitting the single wire into two different wires connected to the same node in the second layout, wherein the parasitic parameters of the two different wires are obtained according to the first parasitic parameter.

12. A method for designing an integrated circuit (IC), comprising:
obtaining a first layout of a design, wherein the first layout corresponds to a first process;
extracting a plurality of parasitic parameters from a target object of the first layout;
scaling the parasitic parameters according to a first model corresponding to the first process and a second model corresponding to a second process;
performing a pre-layout simulation based on a schematic netlist of the design with the scaled parasitic parameters;
modifying the design corresponding to the target object until the pre-layout simulation is normal; and
generating a second layout corresponding to the second process according to the schematic netlist and the scaled parasitic parameters after the pre-layout simulation is normal.

13. The method of claim 12, further comprising:
manufacturing the IC with the second process based on the second layout,
wherein critical dimensions in the first process and the second process are different.

14. The method of claim 12, wherein generating the second layout corresponding to the second process according to the schematic netlist and the scaled parasitic parameters further comprises:
obtaining a routing constraint according to the scaled parasitic parameters after the pre-layout simulation is normal;
performing a placement and routing operation according to the schematic netlist and the routing constraint to generate the second layout; and
performing a post-layout simulation based on the second layout.

15. A computer-readable storage medium storing instructions that, when executed by a processor, cause the processor to perform a method for designing an integrated circuit (IC), the method comprising:
obtaining a first layout of a design, wherein the first layout corresponds to a first process;
extracting a plurality of parasitic parameters from the first layout;
scaling the parasitic parameters according to a first model corresponding to the first process and a second model corresponding to a second process;
performing a pre-layout simulation based on a schematic netlist of the design with the scaled parasitic parameters; and
generating a second layout corresponding to the second process according to the schematic netlist and the scaled parasitic parameters after the pre-layout simulation is normal.

16. The computer-readable storage medium of claim 15, wherein generating the second layout corresponding to the second process according to the schematic netlist and the scaled parasitic parameters further comprises:
obtaining a routing constraint according to the scaled parasitic parameters after the pre-layout simulation is normal;
performing a placement and routing operation according to the schematic netlist and the routing constraint to generate the second layout; and
performing a post-layout simulation based on the second layout.

17. The computer-readable storage medium of claim 15, wherein scaling the parasitic parameters according to the first model corresponding to the first process and the second model corresponding to the second process further comprises:
obtaining a scaling ratio of square resistances in a first metal layer between the first and second processes; and
scaling parasitic resistances of the parasitic parameters in the first metal layer according to the scaling ratio.

18. The computer-readable storage medium of claim 15, wherein scaling the parasitic parameters according to the first model corresponding to the first process and the second model corresponding to the second process further comprises:
obtaining a scaling ratio of a specific feature according to sizes of the specific feature in the first and second processes; and
scaling parasitic resistances of the parasitic parameters for the specific feature according to the scaling ratio.

19. The computer-readable storage medium of claim 15, wherein scaling the parasitic parameters according to the first model corresponding to the first process and the second model corresponding to the second process further comprises:
obtaining a first parasitic parameter and a second parasitic parameter from the parasitic parameters, wherein the first and second parasitic parameters are extracted from two different wires connected to the same node in the first layout; and
merging the two different wires into a single wire in the second layout, wherein a third parasitic parameter of the single wire is obtained according to the first and second parasitic parameters.

20. The computer-readable storage medium of claim 15, wherein scaling the parasitic parameters according to the first model corresponding to the first process and the second model corresponding to the second process further comprises:
obtaining a first parasitic parameter from the parasitic parameters, wherein the first parasitic parameter is extracted from a single wire in the first layout; and
splitting the single wire into two different wires connected to the same node in the second layout, wherein the parasitic parameters of the two different wires are obtained according to the first parasitic parameter.
